(19) United States
(12) Patent Application Publication
(10) Pub. No.: US 2022/0158413 A1
(43) Pub. Date: May 19, 2022

(54) SEMICONDUCTOR LASER

(71) Applicant: iReach Corporation, Hsinchu (TW)

(72) Inventors: Bing-Cheng LIN, Changhua County (TW); Shou-Lung CHEN, Taipei City (TW); Chi-Hsun HSIEH, Taipei City (TW); Hsin-Chan CHUNG, Hsinchu County (TW)

(21) Appl. No.: 17/526,024

(22) Filed: Nov. 15, 2021

(30) Foreign Application Priority Data
Nov. 17, 2020 (TW) 109140184

(51) Int. Cl. H01S 5/183

(52) U.S. Cl. CPC H01S 5/18308; H01S 5/18361

(57) ABSTRACT

A semiconductor laser includes a base, an epitaxial structure on the base, and a first electrode and a second electrode on the epitaxial structure. The epitaxial structure includes a first semiconductor structure on the base, a second semiconductor structure on the first semiconductor structure, an intermediate layer on the second semiconductor structure, a third semiconductor structure on the intermediate layer, a current-confining layer in the third semiconductor structure, a fourth semiconductor structure on the third semiconductor structure, and an active structure between the third semiconductor structure and the fourth semiconductor structure. The first electrode and the second electrode are on the fourth semiconductor structure, wherein a part of the first electrode passes through the fourth semiconductor structure, the active structure, the current-confining layer and the third semiconductor structure and is connected to the intermediate layer.

### TECHNICAL FIELD

The disclosure relates to a semiconductor laser.

### BACKGROUND

In order to reduce the package size of a vertical cavity surface emitting laser (VCSEL), a flip-chip design is an effective way that avoids additional metal wire bonding, reduces the overall package size, and saves costs of optical components.

### SUMMARY

The disclosure provides a laser device including: a base, having a first surface and a second surface, the first surface being a light exiting surface; an epitaxial structure, located on the base, and sequentially including a first semiconductor structure, a second semiconductor structure on the first semiconductor structure, an intermediate layer on the second semiconductor structure, a third semiconductor structure on the intermediate layer, a current-confining layer in the third semiconductor structure, a fourth semiconductor structure on the third semiconductor structure, and an active structure between the third semiconductor structure and the fourth semiconductor structure; and a first electrode and a second electrode on the fourth semiconductor structure, wherein a part of the first electrode passes through the fourth semiconductor structure, the active structure, the current-confining layer and the third semiconductor structure and is connected to the intermediate layer.

### BRIEF DESCRIPTION OF THE DRAWINGS

To better understand the features and technical contents of the disclosure, embodiments of the disclosure are described in detail with the accompanying drawings below. However, the detailed description and the accompanying drawings are for reference and illustration purposes, and are not to be construed as limitations to the disclosure.

FIG. 1 is a cross-sectional schematic diagram of a semiconductor device according to an embodiment of the disclosure;

FIG. 2A and FIG. 2B are a top schematic diagram and a cross-sectional schematic diagram of a semiconductor device according to another embodiment of the disclosure, respectively;

FIG. 2C is a cross-sectional schematic diagram of a semiconductor device according to another embodiment of the disclosure;

FIG. 3A to FIG. 3J are cross-sectional schematic diagrams of structures formed in steps of a method for manufacturing a semiconductor device of the disclosure;

FIG. 4A to FIG. 4C illustrate a semiconductor device according to another embodiment of the disclosure, wherein FIG. 4A is a top schematic diagram of a semiconductor device of the disclosure, and FIG. 4B and FIG. 4C are cross-sectional schematic diagrams of the semiconductor device in FIG. 4A along line I-I and line II-II, respectively;

FIG. 5 is a top schematic diagram of a semiconductor device according to another embodiment of the disclosure;

FIG. 6A to FIG. 6C illustrate a semiconductor device according to another embodiment of the disclosure, wherein FIG. 6A is a top schematic diagram of a semiconductor device of the disclosure, and FIG. 6B and FIG. 6C are cross-sectional structural schematic diagrams of the semiconductor device in FIG. 6A along line A-A and line B-B, respectively;

FIG. 7A and FIG. 7B illustrate a semiconductor device according to another embodiment of the disclosure, wherein FIG. 7A is a top schematic diagram of a semiconductor device of the disclosure, and FIG. 7B is a cross-sectional structural schematic diagram of the semiconductor device in FIG. 7A along line I′-I′; and

FIG. 8A to FIG. 8C illustrate a semiconductor module according to another embodiment of the disclosure, wherein FIG. 8A is a three-dimensional structural schematic diagram of the semiconductor device in FIG. 6A fixed on a carrier plate, FIG. 8B is a cross-sectional structural schematic diagram of the semiconductor module in FIG. 8A along line Y-Y, and FIG. 8C is a cross-sectional structural schematic diagram of the semiconductor module in FIG. 8A along line X-X.

### DETAILED DESCRIPTION OF THE EMBODIMENTS

The concept of the disclosure is described by way of embodiments with reference to the accompanying drawings below. In the drawings or description, similar or identical parts are denoted by the same element symbols or numerals. In addition, the drawings are presented for better understanding, and the thicknesses and shapes of the layers in the drawings are not drawn to their actual sizes or ratio relations. It should be noted that, elements that are not depicted in the drawings or not described in the description are forms that are generally known to a person skilled in the art.

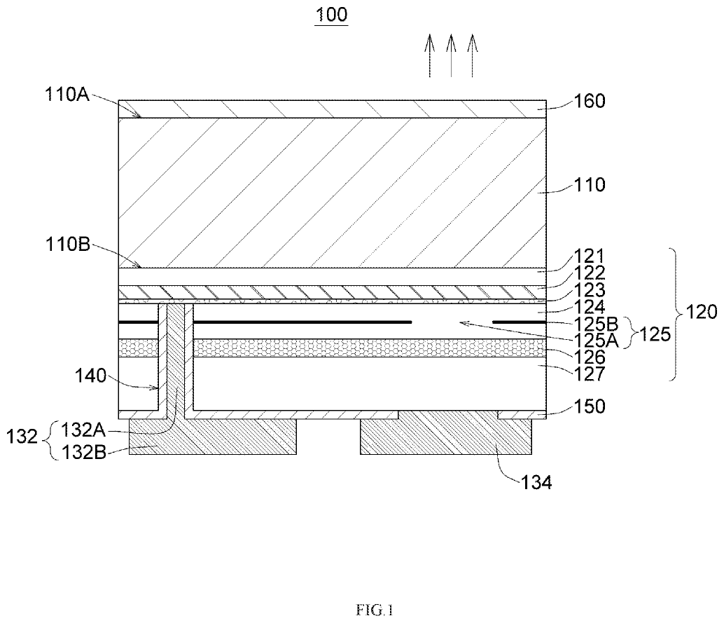

Refer to FIG. 1 showing a cross-sectional schematic diagram of a semiconductor device according to an embodiment of the disclosure. The semiconductor device may be a light-emitting diode (LED), a laser diode, a photodiode or a solar cell. The semiconductor device 100 of the embodiment is a laser diode, and includes a base 110, an epitaxial stacked layer 120 formed on the base 110, and a first electrode structure 132 and a second electrode structure 134 on the epitaxial stacked layer 120. The base 110 is a gallium arsenide (GaAs) substrate having high transmittance, and has a first surface 110A and a second surface 110B. A light exiting surface (as the direction shown by the arrow in FIG. 1) of the semiconductor device 100 is defined as the first surface 110A. The epitaxial stacked layer 120 is on the second surface 110B of the base 110, and sequentially includes a first semiconductor structure 121, a second semiconductor structure 122, an intermediate layer 123, a third semiconductor structure 124, an active structure 126 and a fourth semiconductor structure 127.

In this embodiment, the base 110 includes a dopant so as to have a p-type or n-type conductivity type. Alternatively, in another embodiment, the base 110 does not include any dopant or the base 110 is an undoped base layer. The first semiconductor structure 121 includes semiconductor material excluding a dopant to thereby reduce the issue of light absorption by the dopant. The second semiconductor structure 122, the intermediate layer 123, the third semiconductor structure 124 and the fourth semiconductor structure 127 are semiconductor materials including dopants. The second semiconductor structure 122, the intermediate layer 123 and the third semiconductor structure 124 have the same conductivity type, and the third semiconductor structure 124 (or the second semiconductor 122 or the intermediate layer 123) has a different conductivity type from that of the fourth semiconductor structure 127. In this embodiment, the second semiconductor structure 122, the intermediate layer 123 and the third semiconductor structure 124 have a p-type conductivity type, and the fourth semiconductor structure 127 has an n-type conductivity type. In another embodiment, the second semiconductor structure 122, the intermediate layer 123 and the third semiconductor structure 124 have an n-type conductivity type, and the fourth semiconductor structure 127 has a p-type conductivity type. The first electrode structure 132 and the second electrode structure 134 are on the fourth semiconductor structure 127. The dopant may include beryllium, magnesium, zinc, carbon, silicon, antimony or combination thereof.

Selectively, the third semiconductor structure 124 or the fourth semiconductor structure 127 includes a current-confining layer 125. Alternatively, the current-confining layer 125 is formed in the third semiconductor structure 124 or the fourth semiconductor structure 127. The current-confining layer 125 includes a current limiting region 125B, and a current conduction region 125A surrounded and defined by the current limiting region 125B.

The semiconductor device 100 further includes a recess 140 and a protection layer 150. The recess 140 is formed in the epitaxial stacked layer 120. More specifically, the recess 140 is formed in the fourth semiconductor structure 127, the active structure 126 and the third semiconductor structure 124. In other words, the recess 140 passes through the fourth semiconductor structure 127, the active structure 126 and the third semiconductor structure 124, and exposes the intermediate layer 123. The protection layer 150 is filled in the recess 140 and is between the first electrode structure 132 and the fourth semiconductor structure 127. The first electrode structure 132 has a first portion 132A and a second portion 132B. The first portion 132A is filled in the recess 140 and is in contact with the intermediate layer 123, and is electrically connected to the intermediate layer 123. The second portion 132B extends from the first portion 132A and is on the protection layer 150. The second electrode structure 134 is provided on the fourth semiconductor structure 127, and is electrically connected to the fourth semiconductor structure 127.

In this embodiment, the semiconductor device 100 selectively further includes an optical component 160 covering the first surface 110A of the base 110. For example, the optical component 160 may be an anti-reflection element for further reducing interface reflection between the base 110 and the ambient environment for light emitted from the semiconductor device 100, so as to prevent light attenuation of the semiconductor device 100 or to prevent occurrence of interference between the interface-reflected light and the light emitted from the semiconductor device 100. The anti-reflection element may be single-layer or multi-layer structure, and has a refractive index between the refractive index of the base 110 and the refractive index of the ambient environment (for example, air), and is, for example, 1.1 to 1.65. A single-layer anti-reflection element may be formed of a material such as SiₐN_{b}, SiOₓ or MgF₂, and preferably has a thickness that is an odd-number multiple of one-quarter of a peak wavelength of the light emitted from the active structure 126, that is, (α×λ/4×n) (where λ is the peak wavelength, α is an odd number (1, 3, 5, 7 . . . ), and n is the refractive index). The anti-reflection element may also be a multi-layer structure formed by stacking a high-refractive material and a low-refractive material, for example, SiOₓ/TiOₓ or SiOₓ/TiOₓ/SiOₓ.

In this embodiment, the first semiconductor structure 121, the second semiconductor structure 122, the third semiconductor structure 124 and the fourth semiconductor structure 127 may each include a plurality of periodically alternately stacked layers having different refractive indices (for example, periodically alternately stacked AlGaAs layers having a high aluminum content and AlGaAs layers having a low aluminum content), so as to form a distributed Bragg reflector (DBR), so that the light emitted from the active structure 126 can be reflected in the DBR to form coherent light. The refractive indices of the first semiconductor structure 121, the second semiconductor structure 122 and the third semiconductor structure 124 are lower than the refractive index of the fourth semiconductor structure 127, so as to allow the coherent light to be emitted in a direction of the base 110. The materials of the first semiconductor structure 121, the second semiconductor structure 122, the third semiconductor structure 124, the fourth semiconductor structure 127 and the active structure 126 include group III-V compound semiconductors, for example, the AlGaInAs series, AlGaInP series, AlInGaN series, AlAsSb series, InGaAsP series, InGaAsN and series, AlGaAs series, for example, compounds such as AlGaInP, GaAs, InGaAs, AlGaAs, GaAsP, GaP, InGaP, AlInP, GaN, InGaN and AlGaN. In embodiments of the disclosure, if not otherwise specified, the chemical expressions include “a compounds satisfying chemical dosages” and “a compound not satisfying chemical dosages”, wherein “a compound satisfying chemical dosages” is one in which the total element dosage of group III elements is equal to the total element dosage of group V elements, and conversely, “a compound not satisfying chemical dosages” is one in which the total element dosage of group III elements is different from the total element dosage of group V elements. For example, the chemical expression of an AlGaInAs series indicates the inclusion of group III elements including aluminum (Al) and/or gallium (Ga) and/or indium (In), and the inclusion of a group V element including arsenic (As), wherein the total element dosage of the group III elements (Al and/or Ga and/or In) may be equal to or different from the total element dosage of the group V element (As). Moreover, if the compounds represented by the chemical expression above are compounds satisfying chemical dosages, the AlGaInAs series represents (Al_{y1}Ga_{(1-y1)})₁₋ₓ₁Inₓ₁As, where 0≤x1≤1 and 0≤y1≤1; the AlGaInP series represents (Aly₂Ga_{(1-y2)})₁₋ₓ₂Inₓ₂P, where 0≤x2≤1 and 0≤y2≤1; the AlInGaN series represents (Al_{y3}Ga_{(1-y3)})₁₋ₓ₃Inₓ₃N, where 0≤x3≤1 and 0≤y3≤1; the AlAsSb series represents AlA_{Sx4}Sb₍₁₋ₓ₄₎, where 0≤x4≤1; the InGaAsP series represents Inₓ₅Ga₁₋ₓ₅As_{1-y4}Py₄, where 0≤x5≤1 and 0≤y4≤1; the InGaAsN series represents Inₓ₆Ga₁₋ₓ₆As_{1-y5}N_{y5}, where 0≤x6≤1 and 0≤y5≤1; the AlGaAsP series represents Alₓ₇Ga₁₋ₓ₇As_{1-y6}P_{y6}, where 0≤x7≤1 and

Depending on different materials, the active structure 126 can emit infrared light having a peak wavelength between 700 nm and 1700 nm, red light having a peak wavelength between 610 nm and 700 nm, yellow light having a peak wavelength between 530 nm and 570 nm, green light having a peak wavelength between 490 nm and 550 nm, blue or deep blue light having a peak wavelength between 400 nm and 490 nm, or ultraviolet light having a peak wavelength between 250 nm and 400 nm. In this embodiment, the peak wavelength of the active structure 126 is infrared light between 750 nm and 2000 nm.

The current-confining layer 125 may be formed by an oxidation or ion implant process. In this embodiment, when the first semiconductor structure 121, the second semiconductor structure 122, the third semiconductor structure 124, the active structure 126 and the fourth semiconductor structure 127 include a plurality of layers and all include aluminum, the aluminum content of one or more layers of the third semiconductor structure 124 can be designed to be greater than 97% (defined as the current-confining layer 125) and greater than the contents of aluminum of the active structure 126, other layers of the third semiconductor structure 124, the second semiconductor structure 122, the first semiconductor structure 121 and the fourth semiconductor structure 127. Thus, after oxidation is performed, the layers or the part of the layers having aluminum contents greater than 97% are oxidized to form the current-confining region 125B (for example, aluminum oxide), and the part that is not oxidized becomes the current conduction region 125A. During oxidation, oxygen undergoes an oxidation reaction with the epitaxial stacked layer 120 through the recess 140.

Materials of the first electrode structure 132 and the second electrode structure 134 include metal materials, for example, gold (Au), tin (Sn), titanium (Ti), copper (Cu), silver (Au), germanium (Ge), platinum (Pt), palladium (Pd), nickel (Ni) or an alloy thereof.

In this embodiment, the material of the intermediate layer 123 is different from those of the first semiconductor structure 121, the second semiconductor structure 122 and the third semiconductor structure 124. The intermediate layer 123 may be single-layer or multi-layer and serves as an etch stop layer for controlling the depth of the recess 140 by etching process. The intermediate layer 123 includes a semiconductor material, for example, GaAs or InGaP, and has a thickness that is an odd-number multiple of ¼n of the peak wavelength of light emitted by the active structure 126, where n is a refractive index. In one embodiment, because the material of the intermediate layer 123 is different from those of the first semiconductor structure 121, the second semiconductor structure 122 and the third semiconductor structure 124, the optical characteristics (for example, reflectance and threshold current (Ith)) of the semiconductor device 100 are affected. Therefore, the thickness of the intermediate layer 123 is designed to be between 0.05 μm and 0.5 μm. In one embodiment, the intermediate layer 123 may possibly reduce lateral current spreading, and thus the second semiconductor layer 122 may be provided for considerations of optical characteristics and may also further serve as a current spreading layer. When the intermediate layer 123 is multi-layer (for example, including two layers, wherein the first layer is InGaP and the second layer is GaAs), the total of the thicknesses of the multiple layers is between 0.05 μm and 0.5 μm.

In one embodiment, when the first semiconductor structure 121, the second semiconductor structure 122 and the third semiconductor structure 124 are all DBRs, the number of pairs of the periodically alternately stacked layers in the first semiconductor structure 121 may be greater than, equal to or smaller than that of the second semiconductor structure 122, or/and the number of pairs of the periodically alternately stacked layers in the first semiconductor structure 121 may be greater than, equal to or smaller than that of the third semiconductor structure 124. In one embodiment, the number of pairs of the layers of the second semiconductor structure 122 may be smaller than the number of pairs of the layers of the third semiconductor structure 124. In one embodiment, the number of pairs of the layers of the first semiconductor structure 121 may be 5 to 15 pairs, the number of pairs of the layers of the second semiconductor structure 122 may be 2 to 5 pairs, and the number of pairs of the layers of the third semiconductor structure 124 may be 5 to 15 pairs.

In one embodiment, according to requirements on optical characteristics, the total of the numbers of pairs of the layers of the first semiconductor structure 121, the second semiconductor structure 122 and the third semiconductor structure 124 is smaller than the number of pairs of the layers of the fourth semiconductor structure 127, for example, the total of the numbers of pairs of the layer of the first semiconductor structure 121, the second semiconductor structure 122 and the third semiconductor structure 124 is 15 to 25 pairs, and the number of pairs of the layers of the fourth semiconductor structure 127 is 30 to 60 pairs.

In one embodiment, a p-type semiconductor layer has a lower doping concentration than an n-type semiconductor layer in the aspect of a manufacturing process, and the total of the numbers of pairs of the layers of the second semiconductor structure 122 and the third semiconductor structure 124 is smaller than the number of pairs of the layers of the fourth semiconductor structure 127 in the aspect of design. Thus, the conductivity type of the first semiconductor structure 122 and the third semiconductor structure 124 may be designed as p-type, and the conductivity type of the fourth semiconductor structure 127 may be designed as n-type, thereby reducing the series resistance and enhancing light emitting efficiency of the overall semiconductor device.

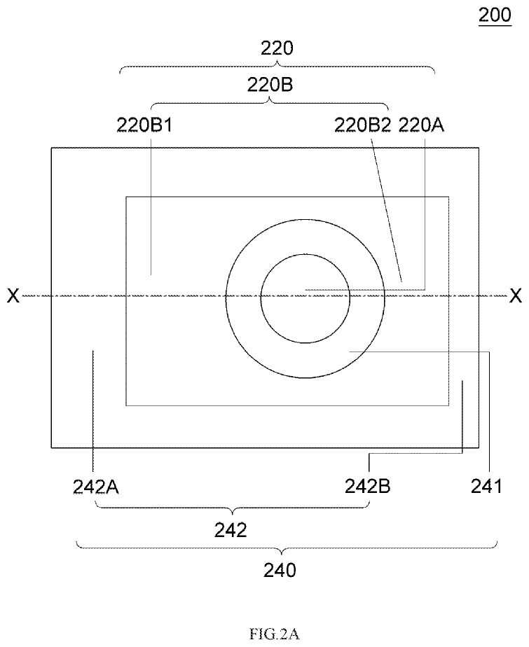

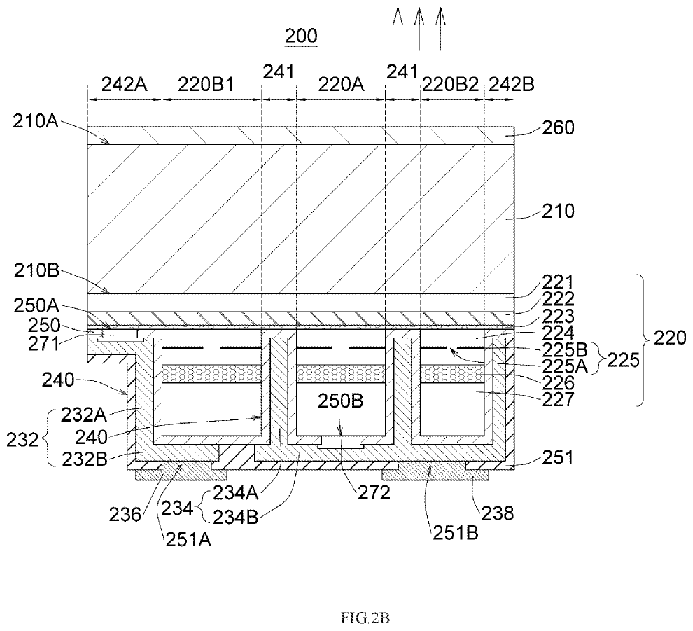

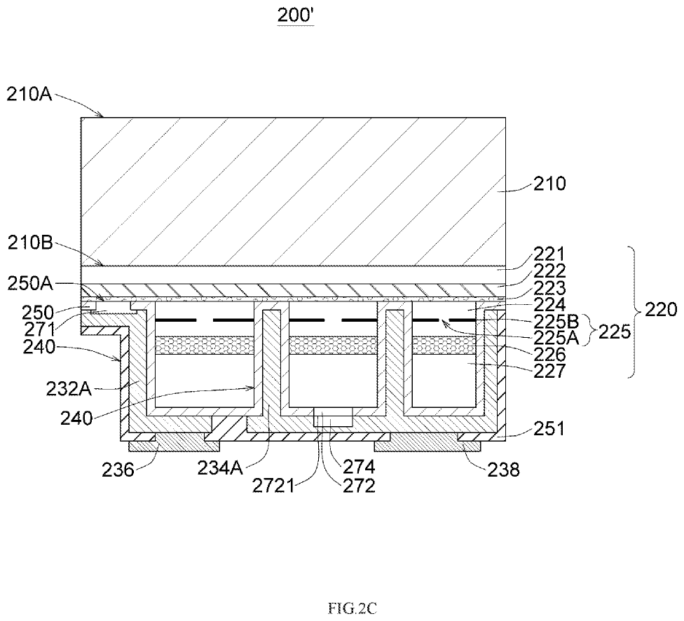

FIG. 2A shows a top schematic diagram of a semiconductor device according to another embodiment of the disclosure, and FIG. 2B shows a cross-sectional schematic diagram of the semiconductor device in FIG. 2A along line X-X. For clarity of the drawing, a partial structure is depicted in FIG. 2A. The semiconductor device 200 of the embodiment is a laser device. A semiconductor device 200 of this embodiment has a structure similar to that of the disclosed embodiment above, wherein components or devices corresponding to similar symbols or numerals are similar to identical components or devices.

In this embodiment, as shown in FIG. 2A, a recess 240 has a first recess region 241 and a second recess region 242. The second recess region 242 surrounds the first recess region 241, and the first recess region 241 and the second recess region 242 are mutually separated and are not in communication. The recess 240 is formed in the epitaxial stacked layer 220 so as to divide the epitaxial stacked layer 220 into a first epitaxial region 220A and a second epitaxial region 220B. The first epitaxial region 220A and/or the second epitaxial region 220B include(s) a part of the epitaxial stacked layer 220 (the third semiconductor structure 224, the active structure 226 and the fourth semiconductor structure 227). The first epitaxial region 220A and the second epitaxial region 220B are mutually separated and are not connected, that is, parts of the epitaxial stacked layer 220 (the third semiconductor structure 224, the active structure 226 and the fourth semiconductor structure 227) are not mutually connected. The first epitaxial region 220B surrounds the first epitaxial region 220A. The first recess region 241 is between the first epitaxial region 220A and the second epitaxial region 220B, and the second epitaxial region 220B is between the first recess region 241 and the second recess region 242.

More specifically, as shown in FIG. 2B, the recess 240 is formed in the third semiconductor structure 224, the active structure 226 and the fourth semiconductor structure 227. In other words, the recess 240 passes through the fourth semiconductor structure 227, the active structure 226 and the third semiconductor structure 224, and exposes the intermediate layer 225. Moreover, the recess 240 is subsequently treated by an oxidation process so as to form the current-confining layer 225. The current-confining layer 225 includes a current limiting region 225B and a current conduction region 225A.

As shown in the cross-sectional diagram of FIG. 2B, the second recess region 242 includes a first area 242A and a second area 242B, and the second epitaxial region 220B includes a first block 220B1 and a second block 220B2. The first recess region 241 is between the first area 242A and the second area 242B. The first epitaxial region 220A is between the first block 220B1 and the second block 220B2. Observing from the top view of FIG. 2A, the first block 220B1 and the second block 220B2 are mutually connected. However, it is known from the cross-sectional diagram in FIG. 2B that, the first block 220B1, the second block 220B2 and the first epitaxial region 220A are mutually separated due the first recess region 241 formed in between.

As shown in FIG. 2B, the semiconductor device 200 further includes a first protection layer 250, a second protection layer 251, a first electrode structure 232, a second electrode structure 234, a third electrode structure 236 and a fourth electrode structure 238. The first protection layer 250 covers the fourth semiconductor structure 227, and is filled in the recess 240 so as to cover a bottom surface and a side surface of the recess 240. The first protection layer 250 is formed as having a first opening 250A and a second opening 250B, so as to expose a part of the intermediate layer 223 and a part of the fourth semiconductor structure 227, respectively. In this embodiment, the semiconductor device 200 further includes a first contact layer 271 and a second contact layer 272. The first contact layer 271 is in the first opening 250A so as to contact with and be electrically connected to the intermediate layer 223, and the second contact layer 272 is in the second opening 250B so as to contact with and be electrically connected to the fourth semiconductor structure 227.

The first electrode structure 232 has a first portion 232A and a second portion 232B. The first portion 232A is filled in the first area 242A of the second recess region 242. The second portion 232B is connected to the first portion 232A and is on the first block 220B1. The second electrode structure 234 has a third portion 234A and a fourth portion 234B. The third portion 234A is filled in the first recess region 241 and the second area 242B of the second recess region 242. The fourth portion 234B is connected to the third portion 234A and is on the first epitaxial region 220A and the second block 220B2. The second protection layer 251 is on the first electrode structure 232 and the second electrode structure 234, and has a third opening 251A and a fourth opening 251B. The third electrode structure 236 is on the second protection layer 251 and is filled in the third opening 251A, and is electrically connected to the third semiconductor structure 224 through the first electrode structure 232, the first contact layer 271 and the intermediate layer 223. The fourth electrode structure 238 is on the second protection layer 251 and is filled in the fourth opening 251B, and is electrically connected to the fourth semiconductor structure 227 through the second electrode structure 234 and the second contact layer 272.

According to the disclosure, the first block 220B1 and the second block 220B2 allow surfaces of the first electrode structure 232 and the second electrode structure 234 to be substantially on the same horizontal surface, and also because the third electrode structure 236 and the fourth electrode structure 238 are respectively on the first electrode structure 232 and the second electrode structure 234, surfaces of the third electrode structure 236 and the fourth electrode structure 238 are also substantially on the same horizontal surface, so as to allow the semiconductor device 200 to be later easily connected to an external circuit by solder and to enhance practicability of the semiconductor device 200. In this embodiment, the second contact layer 272 is electrically connected to only the fourth semiconductor structure 227 in the first epitaxial region 220A but is not electrically connected to the fourth semiconductor structure 227 in the second epitaxial region 220B. Thus, only the first epitaxial region 220A emits light and is defined as a light emitting hole.

Refer to FIG. 2C showing a cross-sectional schematic diagram of a semiconductor device according to another embodiment of the disclosure. A semiconductor device 200′ of this embodiment is a laser device, and has a structure similar to that of the semiconductor device 200 disclosed above, wherein components or devices corresponding to similar symbols or numerals are similar to identical components or devices. In this embodiment, the semiconductor device 200′ further includes a mirror layer 274. The second contact layer 272 is formed between the mirror layer 274 and the fourth semiconductor structure 227, and may form an ohmic contact with the fourth semiconductor structure 227.

More specifically, in the embodiment shown in FIG. 2B, because the second contact layer 272 of the semiconductor device 200 needs to provide both reflection and ohmic contact functions at the same time, the material selection of the second contact layer 272 is limited. However, in this embodiment, the second contact layer 272 is designed to have an ohmic contact and the mirror layer 274 has a reflection function, and so a material having a better reflection efficiency may be selected as the material of the mirror layer 274, further enhancing reflection efficiency. Further, the second contact layer 272 may be treated by a planarization process (for example, chemical mechanical polishing (CMP)), so that the second contact layer 272 has a planar upper surface 2721. Thus, the mirror layer 274 subsequently formed on the second contact layer 272 may have better adhesion with the second contact layer 272, so as to reduce the peeling problem between the two layers. The second contact layer 272 may include a conductive oxide material or a metal material.

In one embodiment, the second contact layer 272 includes a conductive oxide material, for example, indium tin oxide (ITO), and indium zinc oxide (IZO). The second contact layer 272 may include a light-transmissive conducting layer. The mirror layer 274 may include a metal material such as gold (Au) or silver (Ag).

Compared to the semiconductor device 200, the semiconductor device 200′ of this embodiment includes the mirror layer 274 and hence has a better reflection efficiency. Thus, when the fourth semiconductor structure 227 is a DBR, given that the same reflection efficiency is maintained, the number of pairs of the periodically alternately stacked layers in the fourth semiconductor structure 227 may be relatively smaller (for example, the number of pairs is 15 to 25 pairs). In other words, compared to the semiconductor device 200, the fourth semiconductor structure 227 of the semiconductor device 200′ of this embodiment may have a smaller thickness, for example, 2.0 μm to 4.5 μm. Moreover, the smaller number of pairs of the layers also provides a lower series resistance, so that the semiconductor device 200′ has a lower forward bias voltage (Vf) and the manufacturing yield rate can be enhanced.

In another embodiment, the number of pairs of the layers of the fourth semiconductor structure 227 can be reduced by means of the mirror layer 274. Thus, when the conductivity type of the fourth semiconductor structure 227 is p-type and the conductivity type of the third semiconductor structure 124 is n-type, the p-type fourth semiconductor structure 227 having a lower doping concentration does not have an increased series resistance as it has a smaller number of pairs of layers. In addition, the n-type third semiconductor structure 124 having a higher doping concentration can assist in horizontal current diffusion, so as to enhance the light emitting efficiency of the overall semiconductor device 200′.

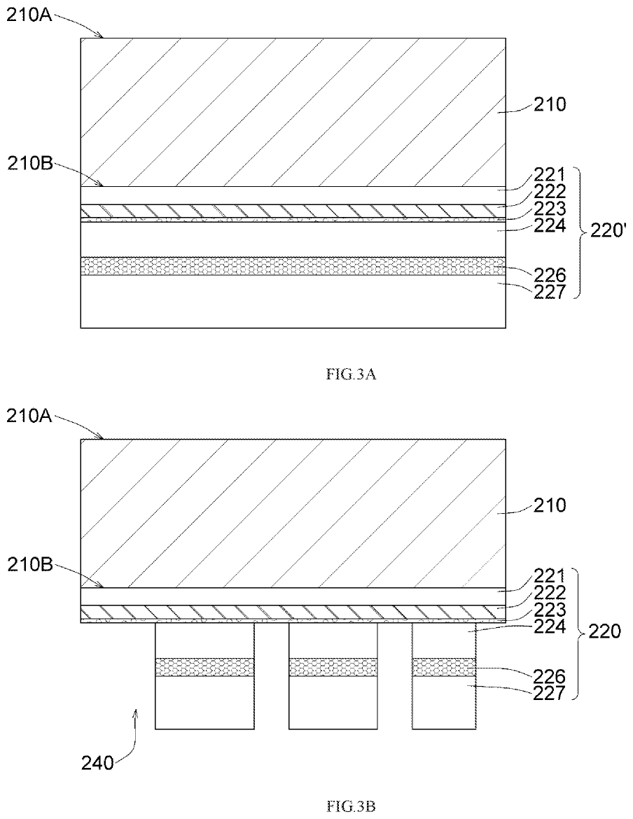

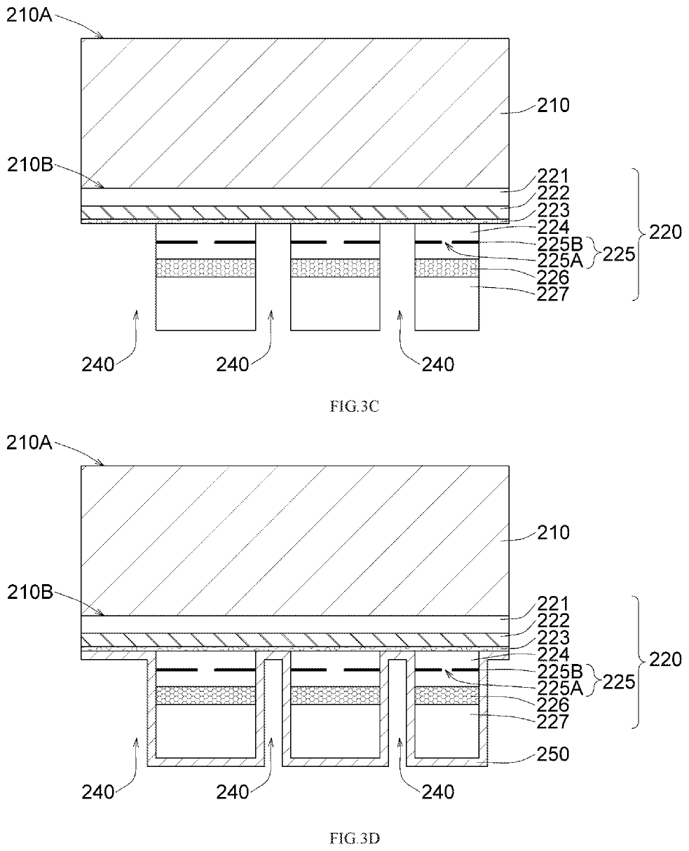

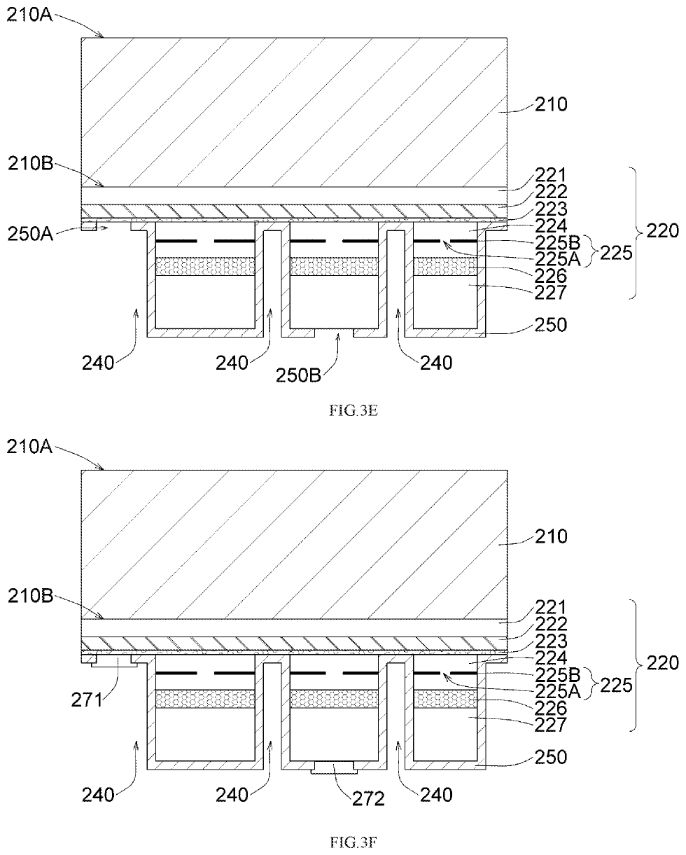

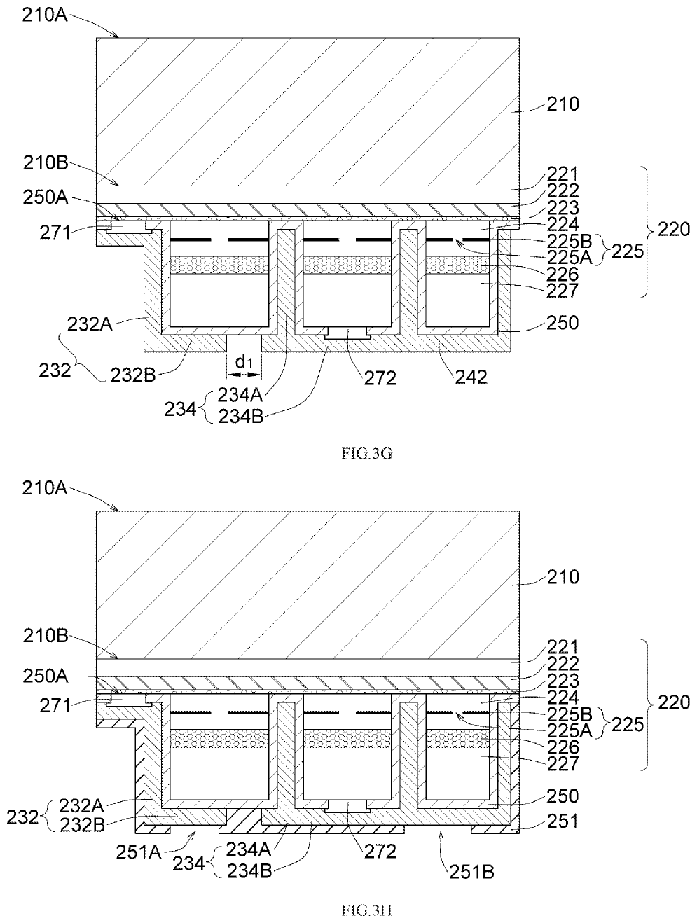

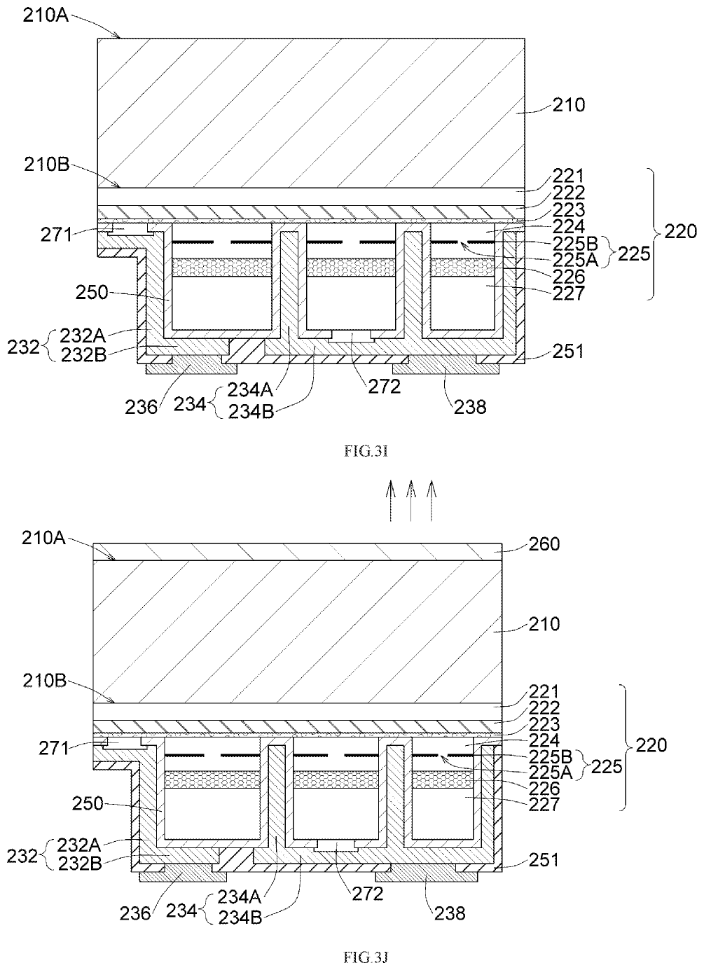

Refer to FIG. 3A to FIG. 3J showing cross-sectional schematic diagrams of structures formed in steps of a method for manufacturing a semiconductor device (for example, the laser device disclosed above) of the disclosure.

First of all, as shown in FIG. 3A, the epitaxial stacked layer 220 is directly grown on the base 210. The base 210 is a growth substrate and has the first surface 210A and the second surface 210B. In this embodiment, the epitaxial stacked layer 220 is formed on the second surface 210B of the base 210, and sequentially includes the first semiconductor structure 221, the second semiconductor structure 222, the intermediate layer 223, the third semiconductor structure 224, the active structure 226 and the fourth semiconductor structure 227.

As shown in FIG. 3B, an etching step is performed to form the recess 240 in the epitaxial stacked layer 220.

As shown in FIG. 3C, an oxidation process is performed via the recess 240 to form the current-confining layer 225 in the third semiconductor structure 224. The current-confining layer 225 includes the current limiting region 225B, and the current conduction region 225A.

As shown in FIG. 3D, a first protection layer 250 is formed. The first protection layer 250 covers the fourth semiconductor structure 227, and is filled in the recess 240 so as to cover the bottom surface and the side surface of the recess 240.

Next, as shown in FIG. 3E, a part of the first protection layer 250 is removed to form the first opening 250A and the second opening 250B, and to expose a part of the intermediate layer 223 and a part of the fourth semiconductor structure 227, respectively.

As shown in FIG. 3F, the first contact layer 271 is formed in the first opening 250A and the second contact layer 272 is formed in the second opening 250B.

As shown in FIG. 3G, the first electrode structure 232 and the second electrode structure 234 are formed. The first electrode structure 232 is in contact with the first contact layer 271 and is electrically connected to the first contact layer 271. The second electrode structure 234 is in contact with the second contact layer 272 and is electrically connected to the second contact layer 272. The first electrode 232 and the second electrode 234 are mutually separated and spaced by a distance d1.

As shown in FIG. 3H, a second protection layer 251 is formed to cover the first electrode 232 and the second electrode 234. The second protection layer 251 is formed as having the third opening 251A and the fourth opening 251B to thereby correspondingly expose parts of the first electrode structure 232 and the second electrode structure 234, respectively.

Next, as shown in FIG. 3I, the third electrode structure 236 and the fourth electrode structure 238 are formed on the exposed parts of the first electrode structure 232 and the second electrode structure 234, respectively.

Finally, an optical component 260 is selectively formed on the first surface 210A of the base 210, as shown in FIG. 3J. In one embodiment, according to application requirements, a thinning or patterning step may be firstly performed on the base 210, and the optical component 260 may then be formed on the first surface 210A of the thinned or patterned base 210. In the embodiment, the base 210 may be a glass substrate (for example, sapphire glass substrate), and the first surface 210A of the base 210 can be patterned to form a structure surface so that the base 210 can be used as an optical component. Alternatively, in another embodiment, the base 210 may firstly undergo a nano imprinting step to directly form an optical component.

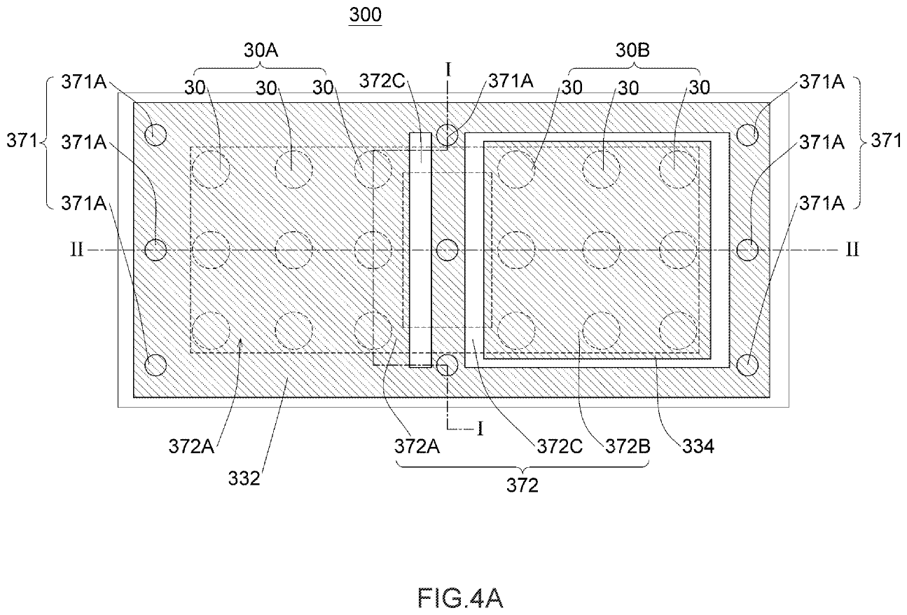

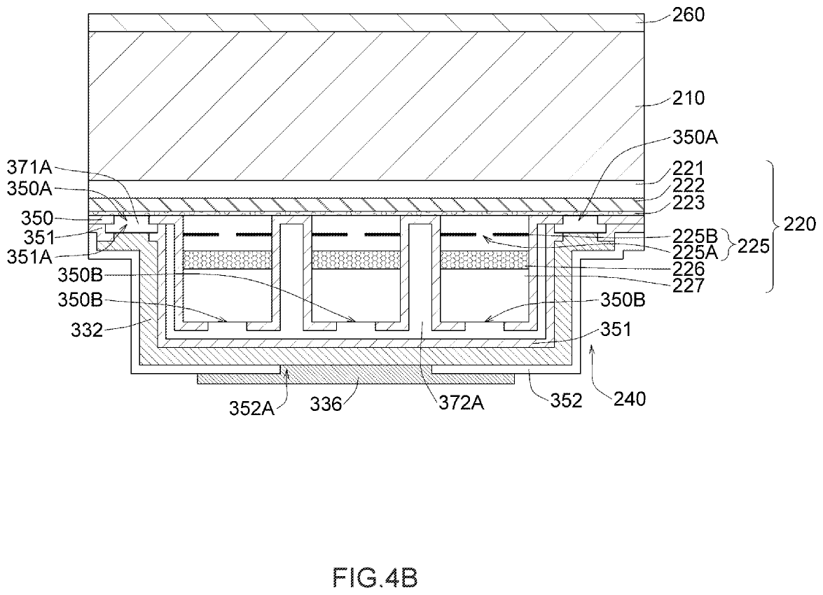

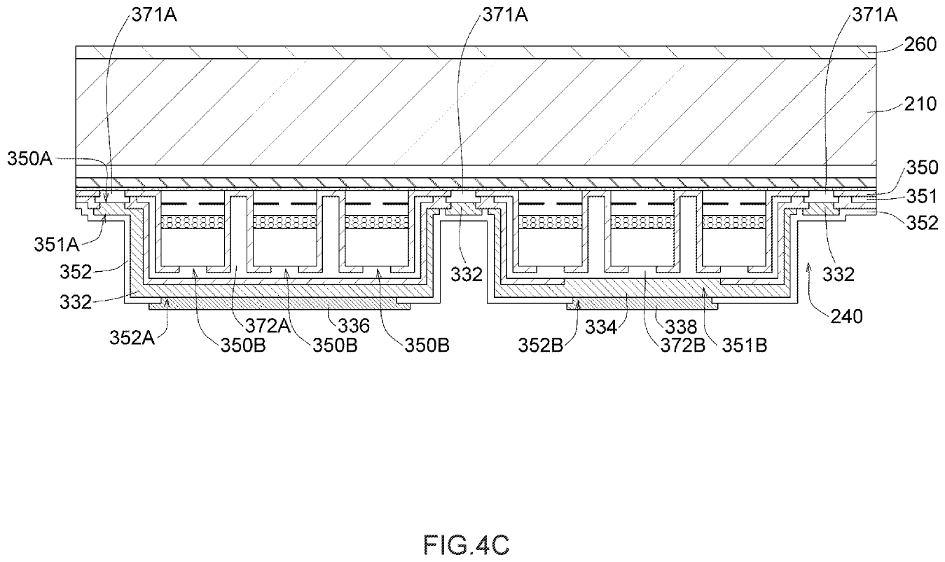

Refer to FIG. 4A showing a top schematic diagram of a semiconductor device according to another embodiment of the disclosure. A semiconductor device 300 of the embodiment may be a laser device. FIG. 4B shows a cross-sectional structural schematic diagram of the semiconductor device 300 in FIG. 4A along line I-I, and FIG. 4C shows a cross-sectional structural schematic diagram of the semiconductor device 300 in FIG. 4A along line II-II. For clarity of the drawing, a partial structure is depicted in FIG. 4A. The semiconductor device 300 of this embodiment has a structure similar to that of the semiconductor device 200 disclosed above, wherein components or devices corresponding to similar symbols or numerals are similar to identical components or devices. In this embodiment, the semiconductor device 300 has a plurality of light emitting holes and a plurality of first openings 350A and second openings 350B, and a first contact layer 371 includes a plurality of contact portions 371A. The contact portions 371A are not mutually connected and may be shaped as circles, rectangles or irregular shapes in top view.

More specifically, in the embodiment shown in FIG. 4A to FIG. 4C, the semiconductor device 300 includes the epitaxial stacked layer 220 and the recess 240. The recess 240 is formed in the epitaxial stacked layer 220 so as to divide the epitaxial stacked layer 220 into a plurality of epitaxial regions, each of which defines a light emitting hole 30. Moreover, each light emitting hole 30 may also be defined by the current conduction region 225A. Each epitaxial region includes a part of the epitaxial stacked layer 220 (the third semiconductor structure 224, the active structure 226 and the fourth semiconductor structure 227). The plurality of epitaxial regions include a first array 30A and a second array 30B. In the embodiment in FIG. 4A, the first array 30A includes nine epitaxial regions and the second array 30B includes nine epitaxial regions.

Referring to both FIG. 4A and FIG. 4B, the semiconductor device 300 includes a first protection layer 350. The first protection layer 350 is filled in the recess 240 and is formed as having a plurality of first openings 350A and exposes the intermediate layer 223. Next, the first contact layer 371 is formed in the plurality of first openings 350A so as to include a plurality of mutually separated contact portions 371A. Each contact portion 371A is in contact with and electrically connected to the intermediate layer 223.

As shown in FIG. 4A and FIG. 4C, the first protection layer 350 is also formed to have a plurality of second openings 350B so as to expose the fourth semiconductor structure 227. A second contact layer 372 is formed in the plurality of second openings 350B so as to contact with and be electrically connected to the fourth semiconductor structure 227 in each epitaxial region. More specifically, the second contact layer 372 includes a first contact block 372A, a second contact block 372B and a connection block 372C. The first contact block 372A and the second contact block 372B respectively correspond to the first array 30A and the second array 30B. The connection block 372C is for connecting the first contact block 372A and the second contact block 372B. The width of the connection block 372C is smaller than the width(s) of the first contact block 372A and/or the second contact block 372B. The first contact block 372A is directly in contact with and connected to the fourth semiconductor structure 227 of the epitaxial stacked layer in the first array 30A, and the second contact block 372B is in direct contact with and electrically connected to the fourth semiconductor structure 227 of the epitaxial stacked layer in the second array 30B.

As shown in FIG. 4B and FIG. 4C, the semiconductor device 300 further includes a second protection layer 351, a first electrode structure 332 and a second electrode structure 334. The second protection layer 351 is on the first protection layer 350 and the second contact layer 372. The second protection layer 351 has a plurality of third openings 351A and fourth openings 351B. The third openings 351A expose the contact portion 371A, and the fourth openings 351B expose the second contact block 372B of the second contact layer 372 but does not expose the first contact block 371B. The first electrode structure 332 is formed on the first contact layer 371 through the plurality of third openings 351A, and is in contact with and electrically connected to each first contact block 371. As described above, the contact blocks 371B are mutually separated and not physically connected, but become mutually electrically connected through the first electrode structure 332. The second electrode structure 334 is filled in the fourth opening 351B, and is physically connected to the second block 372B but not physically connected to the first contact block 372A of the second contact layer 372. In this embodiment, a part of the first electrode structure 332 surrounds the second electrode structure 334.

The semiconductor device 300 further includes a third protection layer 352, a third electrode structure 336 and a fourth electrode structure 338. The third protection layer 352 is on the first electrode structure 332 and the second electrode structure 334, and has a fifth opening 352A and a sixth opening 352B. The fifth opening 352A exposes a part of the first electrode structure 332, and the sixth opening 352B exposes a part of the second electrode structure 334. The third electrode structure 336 is on the third protection layer 352 and is filled in the fifth opening 352A, and is electrically connected to the third semiconductor structure 224 through the first electrode structure 332, the contact portion 371A of the contact the first contact layer 371, and the intermediate layer 223. The fourth electrode structure 338 is on the third protection layer 352 and is filled in the sixth opening 352B, and is electrically connected to the fourth semiconductor structure 227 in each epitaxial region through the second electrode structure 334, and the first contact block 372A and the second contact layer block 372B of the second contact layer 372. As described above, when a current is injected in the semiconductor device 300, each light emitting hole in the first array 30A and the second array 30B can emit light.

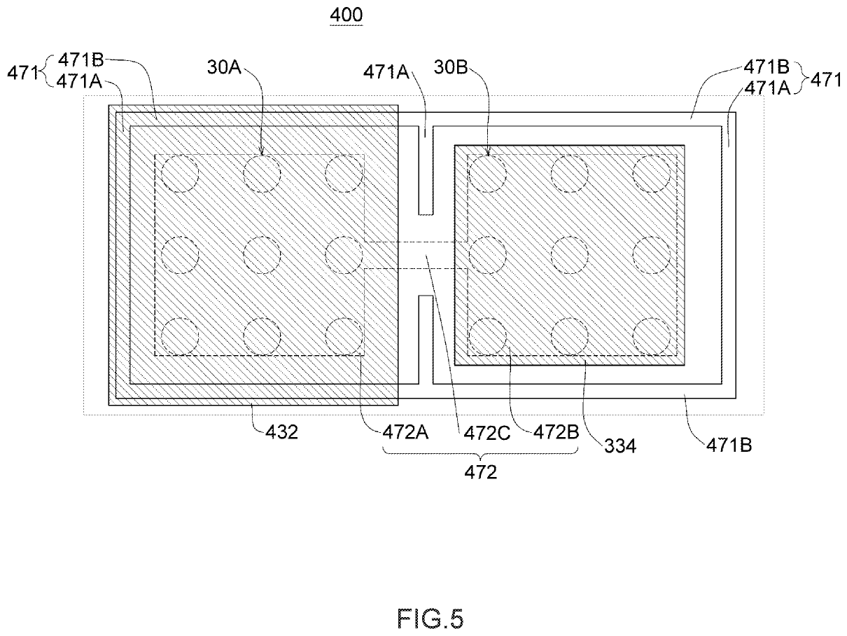

Refer to FIG. 5 showing a top schematic diagram of a semiconductor device according to another embodiment of the disclosure. For clarity of the drawing, a partial structure is depicted in FIG. 5. A semiconductor device 400 of the embodiment may be a laser device. The semiconductor device 400 of this embodiment has a structure similar to that of the semiconductor device 300 disclosed above, wherein components or devices corresponding to similar symbols or numerals are similar to identical components or devices; this embodiment differs in respect of shapes of a first contact layer 471, a second contact layer 472 and a first electrode 432.

In top view of the embodiment shown in FIG. 5, the first contact layer 471 of the semiconductor device 400 includes a plurality of first contact portions 471A and a plurality of contact portions 471B. The first contact portions 471A and the second contact portions 471B respectively extend vertically and horizontally and are mutually connected, so as to surround the first array 30A and the second array 30B. The first contact layer 471 and the second contact layer 472 are non-overlapping in top view. The second contact layer 472 includes a first contact block 472A, a second contact block 472B and a connection block 472C. The connection block 472C is for connecting the first contact block 472A and the second contact block 472B. The first electrode structure 432 is in contact with and electrically connected to only a part of the first contact portions 471A and the second contact portions 471B. When a current is injected in the semiconductor device 400, the first contact portions 471A and the second contact portions 471B are mutually connected, such that current can be transmitted to the entire semiconductor device 400 although the first electrode structure 432 is in contact with a part of the first contact portions 471A and the second contact portions 471B. Moreover, compared to the semiconductor device 300 in FIG. 4A, because the first electrode structure 432 does not need to contact with all the first contact portions 471A and the second contact portions 471B, the configuration of the first electrode structure 432 and the second electrode structure 332 can have a more flexible design space.

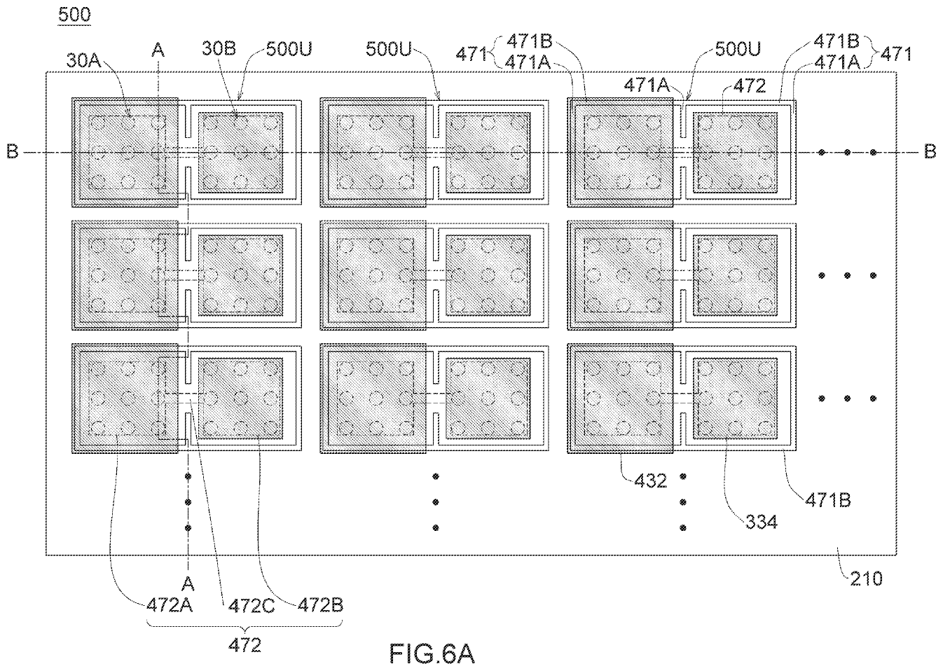

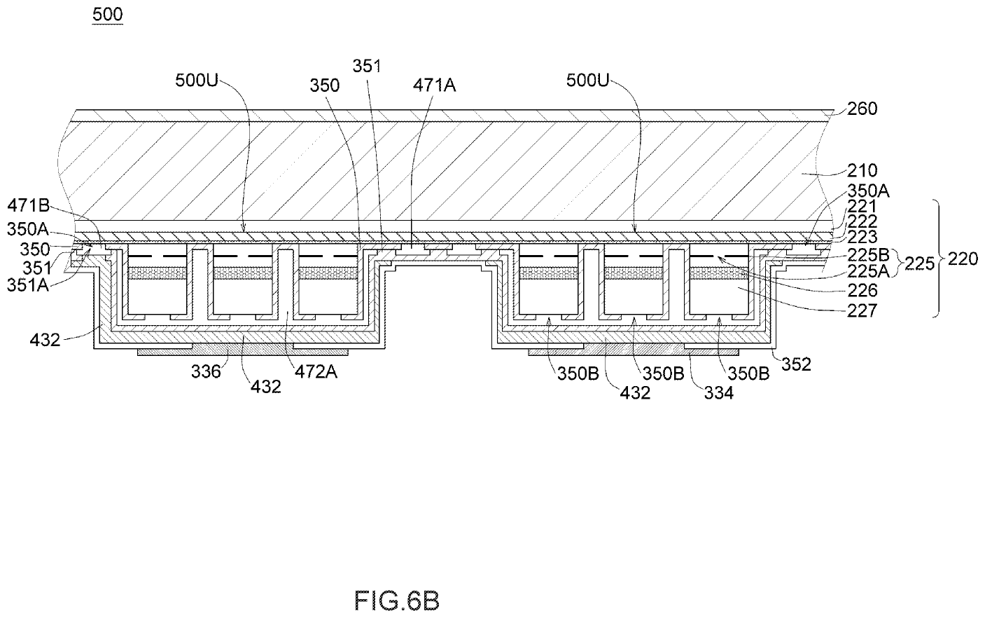

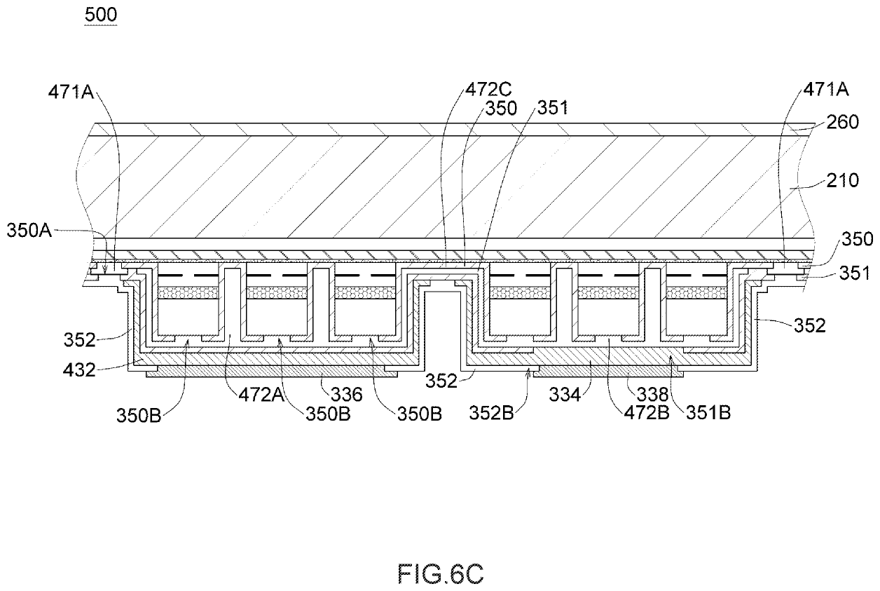

FIG. 6A shows a top schematic diagram of a semiconductor device 500 according to another embodiment of the disclosure. For clarity of the drawing, a partial structure is depicted in FIG. 6A. A semiconductor device 500 of the embodiment may be a laser device. FIG. 6B shows a cross-sectional structural schematic diagram of the semiconductor device 500 in FIG. 6A along line A-A, and FIG. 6C shows a cross-sectional structural schematic diagram of the semiconductor device 500 in FIG. 6A along line B-B. For clarity of the drawing, a partial cross-sectional diagram is depicted in FIG. 6C (one semiconductor unit 500U).

As shown in FIG. 6A to 6C, the semiconductor device 500 includes the base 210 and a plurality of semiconductor units 500U commonly formed on the base 210. Each semiconductor unit 500U includes the epitaxial stacked layer 220 and the recess 240. The recess 240 is formed in the epitaxial stacked layer 220 so as to divide the epitaxial stacked layer 220 into a plurality of epitaxial regions. The plurality of epitaxial regions include a first array 30A and a second array 30B. Each semiconductor unit 500U further includes the first protection layer 350, the second protection layer 351, the third protection layer 352, the first contact layer 471, the second contact layer 472, the first electrode structure 432, the second electrode structure 334, the third electrode structure 336 and the fourth electrode structure 338. The relations of the above components may be referred from the semiconductor device 400 in FIG. 5 and the semiconductor device 300 in FIG. 0.4A, and are omitted herein. In the embodiment in FIG. 4A, the first array 30A includes nine epitaxial regions and the second array 30B includes nine epitaxial regions as an example.

Compared to the structure of the semiconductor device 400, each semiconductor unit 500U does not include the base 210, and the remaining structures are identical. Since the recess 240 does not penetrate through the intermediate layer 223, the second semiconductor layer 222 and the first semiconductor layer 221, the intermediate layer 223, the second semiconductor layer 222 and the first semiconductor layer 221 in each semiconductor unit 500U are mutually connected. The third electrode structures 336 in the individual semiconductor units 500U are mutually separated, and the fourth electrode structures 338 of the individual semiconductor units 500U are also mutually separated, and so each semiconductor unit 500U may be independently controlled.

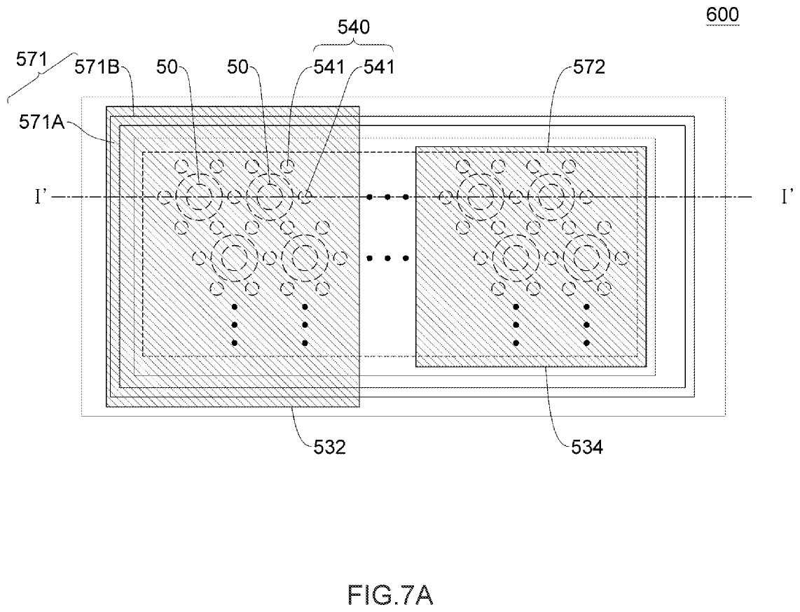

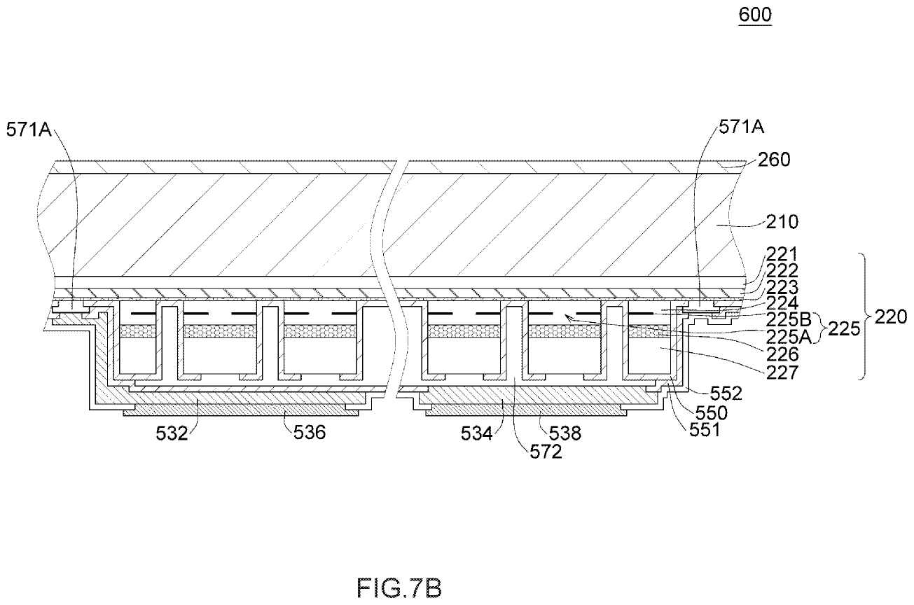

FIG. 7A shows a top schematic diagram of a semiconductor device 600 according to another embodiment of the disclosure. For clarity of the drawing, a partial structure is depicted in FIG. 7A. A semiconductor device 600 of the embodiment may be a laser device. FIG. 7B shows a cross-sectional structural schematic diagram of the semiconductor device 600 in FIG. 7A along line I′-I′. For clarity of the drawing, FIG. 7B depicts only a partial cross-sectional diagram. The semiconductor device 600 has a structure similar to that of the semiconductor device 300 disclosed above, wherein components or devices corresponding to similar symbols or numerals are similar to identical components or devices.

As shown in FIG. 7A to FIG. 7B, the semiconductor device 600 includes the base 210, the epitaxial stacked layer 220, protection layers 550, 551 and 552, a first contact layer 571, a second contact layer 572, and electrode structures 532, 534, 536 and 538. The first contact layer 571 includes a plurality of first contact portions 571A and a plurality of contact portions 571B. The first contact portions 571A and the second contact portions 571B respectively extend vertically and horizontally and are mutually connected, and surrounding the epitaxial stacked layer 220. The semiconductor device 600 of this embodiment includes the recess 540 and a plurality of light emitting holes 50. The recess 540 includes a plurality of dents 541 that are not in mutual communication, and the plurality of dents 541 surround one light emitting hole 50. In this embodiment, six dents 541 that are not in mutual communication surround one light emitting hole 50. Moreover, each light emitting hole 50 may be defined by a current conduction region 525A.

Similarly, during oxidation, oxygen undergoes an oxidation reaction with the epitaxial stacked layer 220 through the dents 541, and so the shape of each light emitting hole 50 is jointly defined by the six surrounding dents 541. At least one of the six dents 541 may simultaneously correspond to two sides thereof to form a current-confining layer to further define the light emitting holes on the two sides. In other words, among the six dents 541 surrounding one light emitting hole 50, at least one dent 541 can share with the adjacent light emitting hole the dent 541 in between.

Observing in top view, the recess 240 of the semiconductor device 300 in FIG. 4 separates the epitaxial stacked layer 220 into a plurality of unconnected epitaxial regions, that is, the third semiconductor structures 224, the active structures 226 and the fourth semiconductor structures 227 of the individual epitaxial regions are not mutually connected. The recess 540 (the dents 541) of the semiconductor device 600 of this embodiment does not separate the epitaxial stacked layer 200 into a plurality of unconnected epitaxial regions. Compared to the semiconductor device 300, a less amount of the epitaxial stacked layer 220 of the semiconductor device 600 is removed. In other words, the area of the epitaxial stacked layer of the semiconductor device 600 is larger, and so the overall heat dissipation efficiency of the semiconductor device 600 can be increased by means of the epitaxial stacked layer.

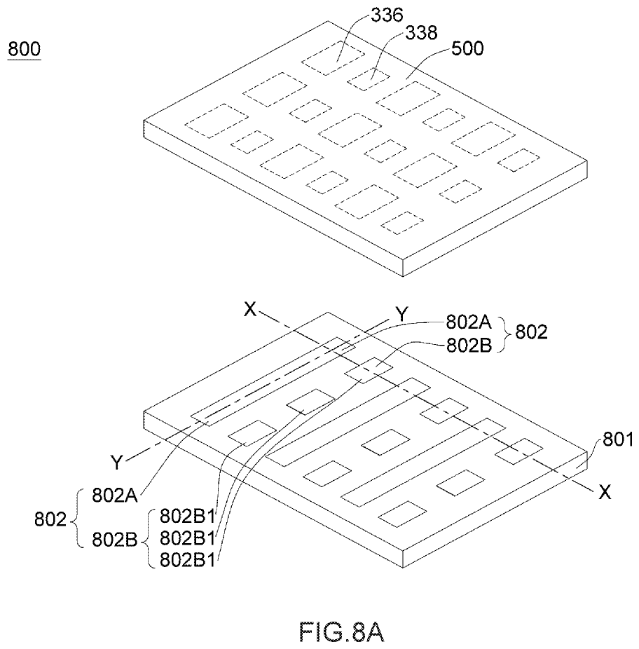

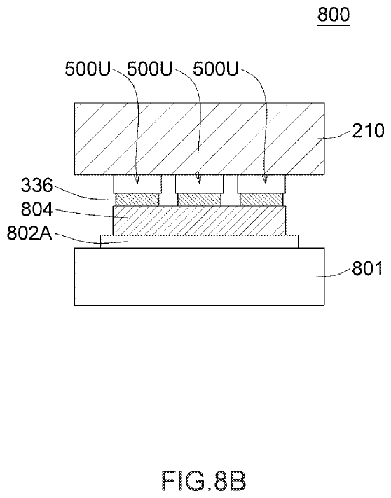

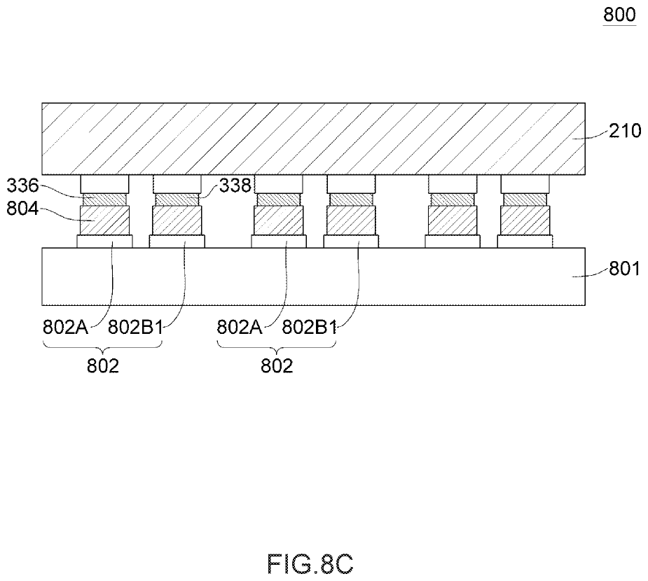

FIG. 8A to FIG. 8C show schematic diagrams of a semiconductor module 800 according to another embodiment of the disclosure. The semiconductor module 800 includes a carrier plate 801, a conductive structure 802 and a semiconductor device 500. FIG. 8A shows a three-dimensional structural schematic diagram of the semiconductor device 500 in FIG. 6A fixed on the carrier plate 801, FIG. 8B shows a cross-sectional structural schematic diagram of the semiconductor module 800 in FIG. 8A along line Y-Y, and FIG. 8C shows a cross-sectional structural schematic diagram of the semiconductor module 800 in FIG. 8A along line X-X.

As shown in FIG. 8A to FIG. 8C, the conductive structure 802 includes a first conductive region 802A and a second conductive region 802B, the third conductive structure 336 of each semiconductor unit 500U is electrically connected to the first conductive region 802A through solder 804, and the fourth electrode structure 338 of each semiconductor unit 500U is electrically connected to the second conductive region 802B through the solder 804. In this embodiment, the first conductive region 802A is shaped as a long strip, and the second conductive region 802B includes a plurality of mutually separated conductive blocks 802B1. Accordingly, when the first conductive region 802A and one of the conductive block 802B1 are electrically connected to an external power supply, the corresponding semiconductor unit 500U emits light, and so each semiconductor unit 500U can be independently controlled.

It should be noted that, the embodiments given in the description of the present invention are merely for illustrating the present invention, and are not to be construed as limitations to the present invention. All modifications and changes made by a person skilled in the art are to be encompassed within the spirit and scope of the present invention. The same or similar components in the different embodiments, or the components denoted by the same element symbols and numerals in different embodiments have the same physical or chemical characteristics. Moreover, in appropriate conditions, combinations, replacements and substitutions of the embodiments of the present invention may be made, and the present invention is not limited to the embodiments above. The connection relation between a specific component described in one embodiment and other components is also applicable to other embodiments, and is similarly to be encompassed within the scope defined by the appended claims.

What is claimed is:

1. A semiconductor laser, comprising:
a base, having a first surface and a second surface, the first surface being a light exiting surface;
an epitaxial structure, located on the second surface of the base, and sequentially comprising:
a first semiconductor structure;
a second semiconductor structure, located on the first semiconductor structure;
an intermediate layer, located on the second semiconductor structure;
a third semiconductor structure, located on the intermediate layer;
a current-confining layer, located in the third semiconductor structure;
a fourth semiconductor structure, located on the third semiconductor structure; and
an active structure, located between the third semiconductor structure and the fourth semiconductor structure; and
a first electrode and a second electrode, located on the fourth semiconductor structure, wherein a part of the first electrode penetrates the fourth semiconductor structure, the active structure and the third semiconductor structure and is connected to the intermediate layer.

2. The semiconductor laser according to claim 1, further comprising:
a optical component, located on the first surface of the base.

3. The semiconductor laser according to claim 1, wherein the base is a gallium arsenide (GaAs) substrate.

4. The semiconductor laser according to claim 1, wherein the intermediate layer comprises p-gallium arsenide (p-GaAs) or p-indium gallium phosphide (InGaP).

5. The semiconductor laser according to claim 4, wherein the intermediate layer has a p-type or n-type conductivity type.

6. The semiconductor laser according to claim 1, wherein a thickness of the intermediate layer is an odd-number multiple of ¼n of a light emitting wavelength of the semiconductor laser, wherein n is a refractive index.

7. The semiconductor laser according to claim 1, further comprising a contact layer located on the fourth semiconductor structure.

8. The semiconductor laser according to claim 7, further comprising a mirror layer located on the contact layer.

9. The semiconductor laser according to claim 8, wherein the mirror layer is embedded in the second electrode.

10. The semiconductor laser according to claim 1, wherein the base includes an undoped base layer.

11. The semiconductor laser according to claim 1, wherein at least one of the first semiconductor structure, the second semiconductor structure, the third semiconductor structure and the fourth semiconductor structure includes a distributed Bragg reflector structure.

12. The semiconductor laser according to claim 11, wherein each of the second semiconductor structure and the third semiconductor structure includes the distributed Bragg reflector structure, and a number of pairs of the distributed Bragg reflector in the second semiconductor structure is smaller than a number of pairs of the distributed Bragg reflector in the third semiconductor structure.

13. The semiconductor laser according to claim 1, wherein a surface of the base includes patterned surface structures.

14. The semiconductor laser according to claim 13, wherein the base is a glass substrate.
